(19) United States
(12) Patent Application Publication
(10) Pub. No.: US 2025/0355832 A1
(43) Pub. Date: Nov. 20, 2025

(54) Reconfigurable Computing Architecture

(71) Applicant: National University of Singapore, Singapore (SG)

(72) Inventors: Jinho Lee, Singapore (SG); Burin Amornpaisannon, Singapore (SG); Trevor Erik Carlson, Singapore (SG)

(73) Assignee: National University of Singapore, Singapore (SG)

(21) Appl. No.: 18/871,323

(22) PCT Filed: May 31, 2023
(86) PCT No.: PCT/SG2023/050388

§ 371 Date: Dec. 3, 2024

(30) Foreign Application Priority Data
Jun. 3, 2022 (SG) 10202250038K

(51) Int. Cl. G06F 15/80; G06F 15/82

(52) U.S. Cl. CPC G06F 15/80; G06F 15/825

(57) ABSTRACT

A computing circuit comprising a plurality of reconfigurable processing elements (PEs); data communication lines connecting an output port of each of the PEs with an input port of each other one of the PEs; wherein the computing circuit is configured to execute a data flow model by configuring at least a second subset of the plurality of PEs to perform a respective discrete computation implementing the data flow model; and wherein a first PE of the second subset of PEs is configured to perform its respective discrete computation on receipt of a ready to receive output signal from one or more destination PEs; wherein the one or more destination PEs are configured to perform a computation on the output of the first PE according to the data flow model.

### TECHNICAL FIELD

This disclosure generally relates to reconfigurable computing architectures or circuits.

### BACKGROUND

This background description is provided for the purpose of generally presenting the context of the disclosure. Contents of this background section are neither expressly nor impliedly admitted as prior art against the present disclosure.

Traditional reconfigurable architectures such as Field Programmable Gate Arrays (FPGAs) and Coarse-Grained Reconfigurable Arrays (CGRAs) are subject to constraints in flexibility and energy efficiency when compared with conventional processors or ASICs. Programming these reconfigurable architectures using low-level programming operations requires expertise in hardware and requires a longer time to program. Traditional spatial architectures may be classified into: Static Placement Static Issue (SPSI), Static Placement Dynamic Issue (SPDI) and Dynamic Placement Dynamic Issue (DPDI).

DPDI: For spatial architectures, the given workloads should be converted to the spatial mapping which is often complicated or time consuming if performed dynamically. Some DPMI architectures are coupled with an OoO (out of order) processor and uses it to generate the OoO execution schedule. As the schedule is generated with an OoO processor, its performance is limited by the host processor. Although the scheduling is performed dynamically, the issue is executed following the fixed schedule. This architecture can make an operation wait longer than needed when its operands are processed early.

SPDI: The static placement tends to be done to minimize the routing costs on the fabric. The spatial architectures of this category share common features in hardware and their execution methods. Each processing units handle multiple instructions and it selects one or more of them per cycle to execute depending on the resources it has. In this way, the number of operations can be fired is limited by the number of processing units. The processing units are often connected using a point-to-point network. Due to the network, poor placement can lead to multi-hop traversal causing long latency.

SPSI: By defining the issue schedule statically, it tends to be more efficient than the dynamic issue architectures while sacrificing flexibility. Some SPSI architectures couple coarse grained reconfigurable fabric with a CPU to efficiently process compute intensive regions. Similar to SPDI architectures, SPDI architectures comprise processing units and their mesh interconnections. The operation executions and data transfers are statically determined by the compiler but it has backup dynamic supports to handle dynamic events that are difficult to predict in the compilation time. Routing is done to guarantee that the operands are ready by the issue time. This can be extremely complicated when it is done using Iterative Modulo Scheduling often taking hours. HyCUBE enables single cycle multi-hop data transfer on a mesh network. It mitigates the complexity of the scheduling caused by the point-to-point data transfer and improves performance. However, though it allows multi-hop data transfer, the wires on the mesh network can be used only once in a cycle. Thus, the SPSI architecture still considers the physical distance between instructions to minimize the latency and contention in routing.

The background architectures lack flexibility in programming and handling dynamic events. Programming FPGA requires expertise in hardware to program them. High Level Synthesis (HLS) tools can help users generate RTL from software but, it is hard to guarantee the optimality of the generated RTL. For CGRAs, even with the larger granularity than FPGAs, finding the mapping of a CDFG based on Modulo Scheduling is known to be NP-Complete.

It is desirable to provide computing architectures that address one or more drawbacks of the known computing architectures or at least provide an alternative.

### SUMMARY

<to be completed after the claims are approved>.

### BRIEF DESCRIPTION OF THE DRAWINGS

Some embodiments of reconfigurable computing architectures or circuits and methods of computation using the architectures in accordance with present disclosure, are described by way of non-limiting example only, with reference to the accompanying drawings in which:

FIG. 1 illustrates a plot of a comparison between the disclosed computing architecture and traditional architectures;

FIG. 2 illustrates a flow chart of dynamic data-driven execution performed by the disclosed computing architecture;

FIG. 3 illustrates an overview of the Dynamic Data-Driven Reconfigurable Architecture;

FIG. 4 illustrates a design of the processing element;

FIG. 5 illustrates ready signal reduction;

FIG. 6 illustrates mapping of an example DFG on 3DRA with 6 PEs;

FIG. 7 illustrates instructions per cycle comparison of the disclosed architecture with HyCUBE and 3DRA in different FIFO sizes;

FIG. 8 illustrates power efficiency comparison with of the disclosed circuits with bother benchmark architectures;

FIG. 9 illustrates an exemplary floorplan of the 128-PE version a computing circuit; and

FIG. 10 illustrates a flowchart of a method of executing a data flow model using a computing circuit according to the embodiments.

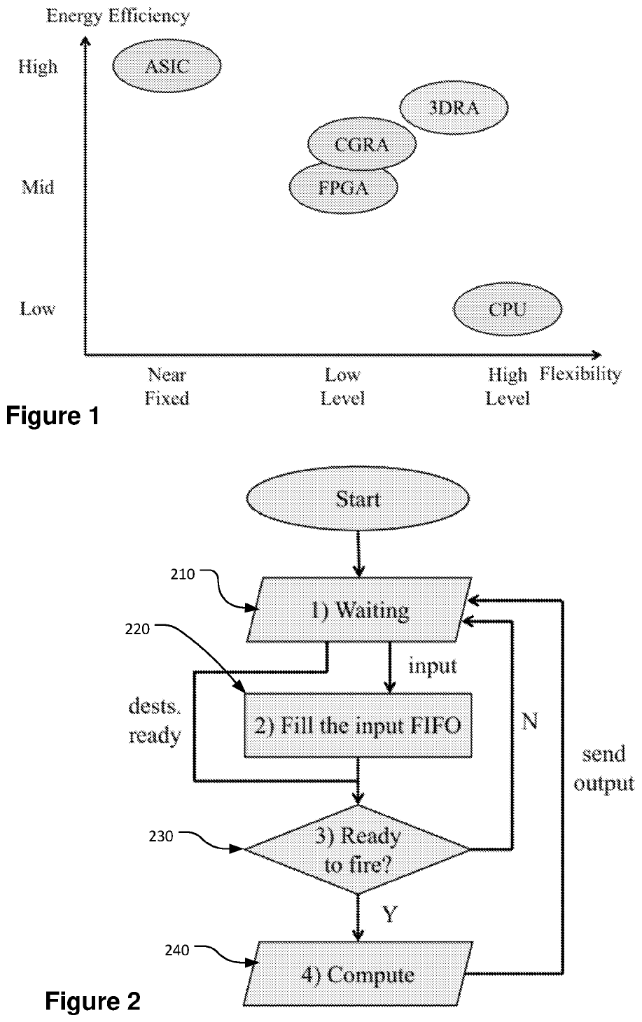

### DETAILED DESCRIPTION

Disclosed embodiments relate to computing circuits, reconfigurable computing architecture, and methods for executing a data flow model using the disclosed circuits or architecture. The embodiments leverage a plurality of reconfigurable processing elements (PEs) wherein a first PE is configured perform its respective discrete computation on receipt of a ready to receive output signal from one or more destination PEs for its output. The computing circuits allow data from the PEs to be broadcast to all the rest of the PEs of the circuit in a single cycle.

The disclosed circuits advantageously provide higher flexibility by directly mapping a control dataflow graph (CDFG) on the hardware and handle dynamic events such as branches and memory accesses at run time as opposed to handling such events before run time. The dynamic nature of the execution advantageously provides improved performance.

The disclosed circuits can advantageously fire operations as soon as their operands are ready. The disclosed circuits also provide for simplified mapping/placement of the CDFG onto the hardware. Each processing element only requires its source operands and the opcode for mapping without the need to consider the routing optimization. Placement of the operands can be performed dynamically.

In the disclosed computing circuits, the issue decision is dynamically made depending on the availability of operands. The disclosed circuits advantageously allow execution of instructions whose inputs are available. At the same time, some embodiments allow transmission of outputs to respective destinations in a single cycle to advantageously enable zero latency, all-to-all communication. The disclosed circuits or architectures advantageously enable contention-free data communication, which simplifies the mapping of instructions on the hardware significantly. Furthermore, without constraints on routing that the background art is subjected to, the disclosed circuits can advantageously provide higher performance.

The disclosed computing architecture is also referred to as 3DRA that can be programmed in O (N) from a CDFG. FPGAs are mostly spatially programmed and CGRAs are programmed in spatio-temporal way. Due to the spatio-temporal programming, when generating CGRA execution schedules, the compiler should predict dynamic events and handle them before happening. It can lead to too conservative schedules. For example, if there is an instruction that takes variable time between 2 to 10 cycles, the compilation should be done assuming that it takes 10 cycles to guarantee the correctness.

Dynamic Data-Driven execution: It is beneficial for the hardware to decide whether all their operands of an instruction have arrived and make a decision to fire it or not. The approach allows more aggressive execution than the conservative static mapping. When an instruction is processed by the disclosed computing circuit, the output is transferred to its destinations through a point-to-point network, which can induce long latency. To reduce the travel distance, in the disclosed computing circuit, multiple operations are mapped at a processing unit so that they can send data between them without traversing the point-to-point network. However, in this case, only one or a few instructions can be executed from a processing element depending on the resources. It leads to the limited number of instructions executed in parallel (Instruction Level Parallelism, or ILP). To maximize ILP, the disclosed embodiments provide an approach to minimize the number of instructions sharing a processing unit and reduce the impact of the data transfer latency at the same time.

Zero latency, all-to-all communication: The point-to-point networks of traditional spatial architectures including CGRAs not only increase the latency in communication but also make the placement and routing complicated. There are several problems that complicates the routing in the point-to-point networks of the background art. First of all, multi-hop data transfer can cause the long latency. This delays the execution of the destination instruction. Secondly, the limited connections between processing units can cause network contention and exacerbate the data transfer delay. To address the limitations of the background architectures, the disclosed embodiments address the difficulties in data communication between instructions by providing an architecture such that the output can reach anywhere in a single cycle and all instructions can send their data at the same time without network contention.

### Dynamic Data-Driven Execution

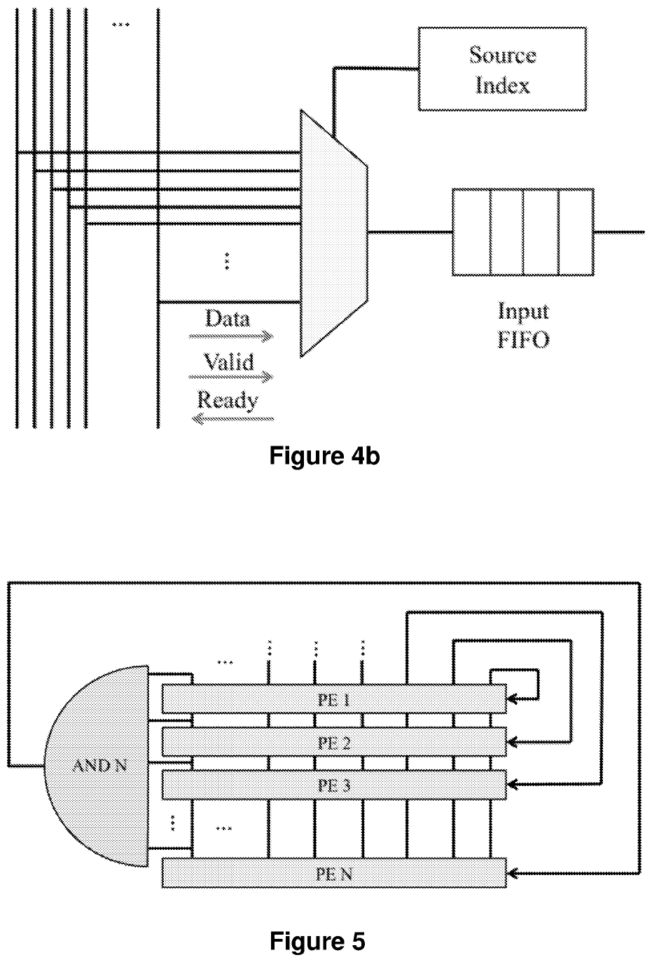

The execution flow of 3DRA is illustrated in FIG. 2. This execution flow is implemented inside the processing element (PE) illustrated in FIGS. 4a and 4b. First of all, the PE waits (step 210) until all of its input operands are ready to be computed, and its destinations are ready to get data. If the instruction requires multiple operands (e.g., binary operation), some operands can arrive earlier than the others. The operands which arrive earlier stay in a FIFO (step 220) until all other operands are ready. When both operands are ready (step 230), the inputs are computed, and the PE determines if it is ready to fire its output data. There are two conditions to assess at step 230 include 1) whether all the operands are ready to be computed and 2) whether all of the destinations are ready to receive the output result. If the two conditions are met, the PE performs the computation at step 240 and sends the output and waits for the input operands and the ready signal from its destinations again. Otherwise, it goes back to the waiting phase directly.

In Phase 1 (210), the PE waits input operands and the ready signals from its destinations. It is beneficial to get all of them at the same time to save the number of idle cycles. In Phase 2 (220), for the correctness of the execution and simplification of the design, the operands have to arrive in the same order with the data firing order between a source PE and a destination PE. In other words, the data arrival order should not be changed on the way depending on the location of the PE. In Phase 3 (230), the PE has to be able to determine if all the operands are ready and the destinations are ready to receive data in a fast way. It is simple to check the operands as the operands are stored in the FIFO within the processing unit. However, to know the readiness of the destination PE, it has to be able to check the status of other PEs with low communication latency. In Phase 4, the PE has to be able to execute the given instruction and sends the output to its destinations with low communication latency. In the flow chart, the phases are illustrated as a sequential flow graph, but the steps can be pipelined to increase throughput.

In summary, the embodiments provide for 1) receiving all the incoming signals in parallel, 2) overseeing the order of the message arrival, 3) checking the readiness of the destinations immediately, 4) delivering the output to the destinations in a single cycle, and pipeline the input and computation & output.

### Hardware Architecture

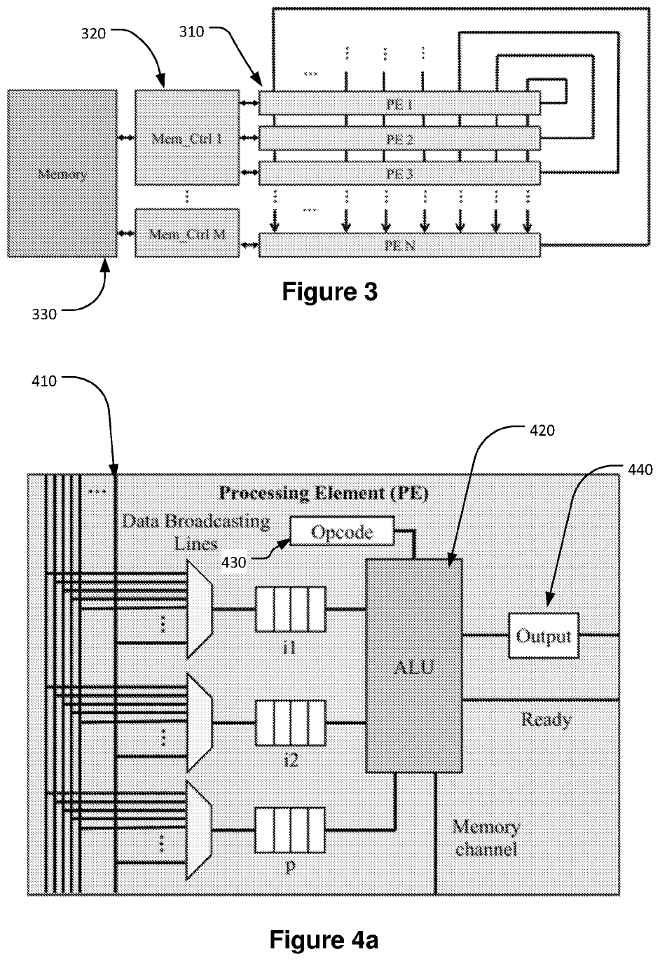

The overview of 3DRA is illustrated in FIG. 3. 3DRA comprises multiple Processing Elements (PEs) 310, memory controllers 320, and scratchpad memories 330. Multiple PEs are deployed to increase the degree of parallelism. They are connected in such a way that data can be broadcast directly to all existing PEs in a single cycle to reduce communication latency. The memory controller is used to send load and store requests from the PEs and forward loaded data from the memory to the PEs. If more than one request arrive at the same time, it selects one of them using an arbiter. When there are multiple memory ports, to support multiple requests, multiple memory controllers are used. The PEs are split into groups as many as the memory controllers, and each group is served by one dedicated memory controller. In this way, it is ensured that all the PEs are connected to one of the memory controllers, simplifying the mapping algorithm as the PEs all have a connection with the memory.

The PE is the key component that does a computation on specific input data based on a given instruction. FIG. 4a shows the design of the PE. Each PE is first reconfigured based on a specific application that is mapped to 3DRA and handles one instruction. All of the PEs have the same design and are connected to the memory controller and other PEs via the data broadcasting lines 410. Note that a PE has input ports as many as the number of PEs, so that it can get all of its operands at the same time without an input port contention. The Ready signal is high by default. When an input FIFO is full, it sends low Ready signal to its source PE specified in Source Index shown in FIG. 4b. From the data broadcasting lines, each multiplexer connected to an Input FIFO selects its source operand using Source Index register. The value of the source index register designates the output of one of the PE as an input for the input FIFO register. When the Valid is high, the incoming Data is queued into the Input FIFO (registers i1, i2, or p etc). In every cycle, the input FIFOs are checked whether the required data operands to be computed are available or not.

When all of the operands are ready and stored in the FIFOs, the PE sends the input data to its Arithmetic-Logic Unit (ALU) 420. Then, it executes the operation as programmed in the Opcode register 430. An ALU consists of a variety of components to support different operations including a multiplier and divider. The multiplier and divider are pipelined to ensure that they do not become the critical path. While it is executing the operation, it can still receive input values from its source PEs as long as the FIFOs are not full. The output of the ALU is stored in the Output register 440 and is sent to other PEs through its data broadcasting line when all of its destinations are ready to receive the output. To handle an if-else block, at the end of the block, a PE mapped with a SELECT instruction determines which input between i1 or i2 is selected to be sent out depending on the input predicate (p) value.

Handling memory operations: If an operation comprises handling a load instruction, then the PE sends the request to the memory controller through the Memory Channel and waits until the response comes back. Then the response is forwarded to the Output register. Note that the memory access latency does not affect the execution flow, in other words, a PE can handle memory operations even if it takes variable time. It allows 3DRA to be used with different memory types such as scratchpad, caches, etc. If the instruction is a store instruction, the PE sends a write request to the memory controller without waiting for a response.

Zero latency, all-to-all communication: By using data broadcasting lines, communication latency is minimized by the disclosed embodiments. A PE can sends its output to all of its destinations at once when all destinations are ready to receive input. When all destination PEs are ready to receive the data, all of the Ready signals through the Data Broadcasting Lines are reduced as shown in FIG. 5. In this way, a PE can be informed as soon as all the destinations are ready to receive. After receiving the ready signal from all destination PEs, the PE broadcasts its output. It enables the PEs to send data to all its destinations in parallel. The destination PEs receive the data at the same time without any network delay. In addition, it simplifies the complexity needed to handle data communication as it guarantees the incoming input data order. The data arrives as soon as the source PE sends it so, the data broadcasting lines preserve the order of data. This arrangement eliminates the possibility of the out-of-order delivery that can happen in a packet switching network.

Programmability: The programmability 3DRA is significantly improved as the design relies on dynamic execution instead of static execution. The mapper of an operation on the is not required to predetermine the data flow of an application, including the time duration of each memory request to be served and data dependencies, using low-level hardware-specific information. Instead, the hardware can determine when to compute and transfer data itself using the ready signal. Due to the homogeneous structure of PEs in the computing circuit and all-to-all broadcasting, the instructions can be placed anywhere on the fabric, which removes optimization phases over resources and routing paths between instructions. Due to the hardware design of 3DRA, to configure a PE, it only requires the source operand indices and its opcode. This component-level re-configurability enables 3DRA to be reconfigured in a quick way, contrary to a fine-grained reconfiguration technique required for FPGAs.

### Example Execution Walk-Through

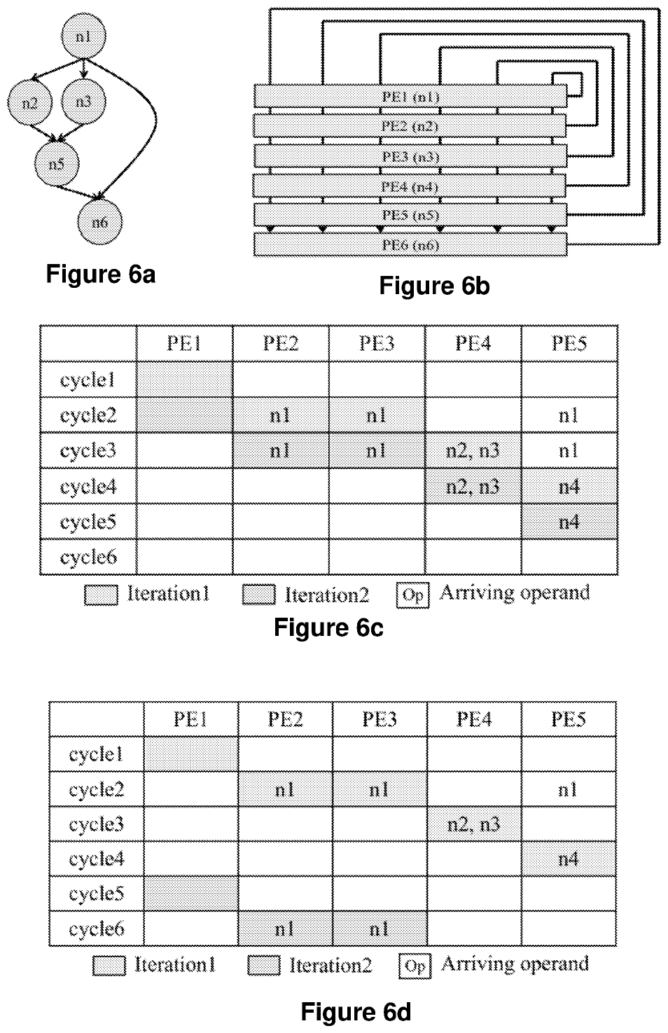

3DRA enables dynamic data-driven execution between the operations mapped on PEs. As soon as input operands arrive and the destinations are ready to receive, a PE fires the computation. Then it broadcasts the output in a single cycle. Here, an example execution flow is shown in FIG. 6. The operations in a dataflow graph in FIG. 6a are sequentially mapped on 3DRA as shown in FIG. 6b. Note that the mapping can be randomly done without considering dependencies between the operations and the physical proximity between dependent operations.

The cycle by cycle execution flow is shown in FIGS. 6c and 6d with 3 entry input FIFOs and input registers, respectively. In FIG. 6c, at the beginning, n1 can fire as the input FIFOs of n2, n3, and n4 are empty, n1 immediately fires. n1's output is broadcasted and the operations that use it selectively receive it. Then, they immediately fire computation. In the next cycle, n5 can compute as it gets operands from n2 and n3. At the same time, n6 gets an operand from n4 but it should wait until it gets data from n5. In cycle 4, the data from n5 arrives and it can compute. When this DFG is a loop, the execution pattern is repeated in the same way in the following cycles. The iterations can be seen as pipelined to expose Loop Level Parallelism, meaning a new iteration can begin before the previous one ends so that multiple iterations can be overlapped.

The use of FIFOs significantly contributes to the performance of 3DRA by allowing PEs quickly send output data and move forward to next iterations. A PE sends its output only if all of the destinations are ready to receive. It means that without the buffering, until a PE fires, it can prevent its source PEs from executing. For example, let's suppose that input registers are deployed instead of the FIFOs. Then, a PE can hold only one input data per operand. FIG. 6d shows how the performance drops without the input FIFOs. At cycle 2, n5 receives input from n1. Until cycle 4, it waits for n4's output. In the meanwhile, n1 waits for the ready signal from n5 as its input register is filled. Because of this, Iteration 2 can begin at cycle 5 and the throughput drops by 4x.

### Experimental Setup

An experimental setup for 3DRA may be implemented in Chisel (The Constructing Hardware in a Scala Embedded Language) and is synthesized using Synopsys Design Compiler version 2019.03 targeting a commercial 22 nm technology node. The configurations of an exemplary embodiment of 3DRA are shown in Table 2. Synopsys VCS-MX 2015.09 was used for gate-level simulation, and Synopsys PrimePower 2019.03 was used for power evaluation.

### Evaluation

TABLE 1
Benchmark characteristics

| Benchmark | # Nodes | # Edges | Domain |
|---|---|---|---|
| aes | 171 | 209 | security |
| array add | 20 | 23 | matrix |
| fft | 67 | 93 | signal processing |
| gemm | 25 | 30 | matrix |
| hpcg | 24 | 30 | hpc |
| kernel symm | 39 | 50 | matrix |
| pedometer | 61 | 80 | monitoring |
| trmm | 11 | 12 | monitoring |

In Table 1, target benchmarks are described. The benchmarks are the innermost loop kernels of various domains in different sizes. The control dataflow graphs (CDFG) are generated using an LLVM based dataflow graph generator such as ecolab nus Morpher_DFG_Generator https://github.com/ecolab-nus/.

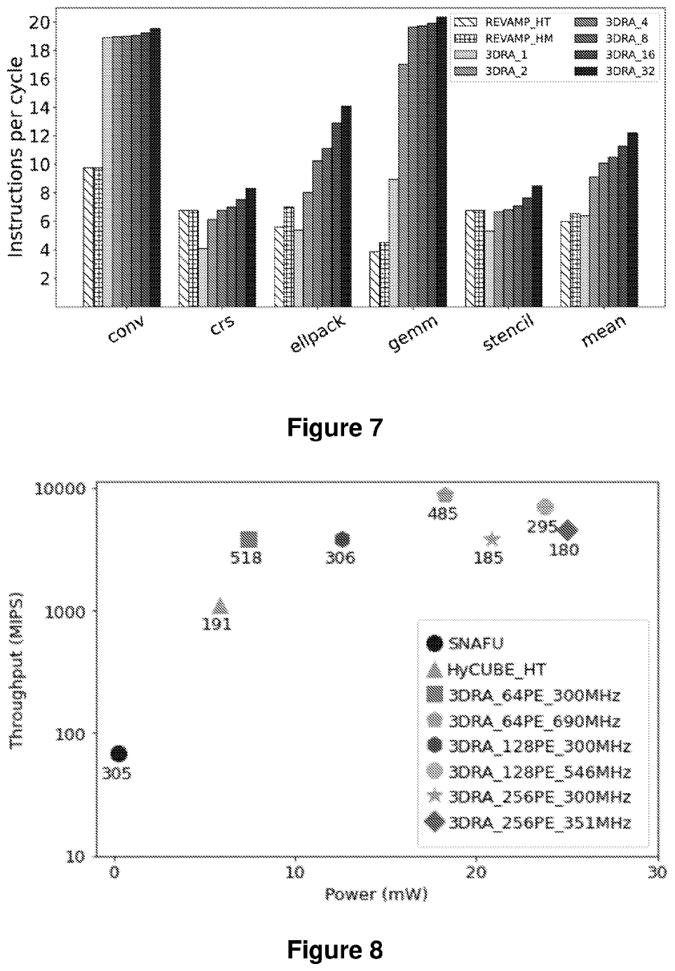

Quality of scheduling: FIG. 7 shows the instructions per Cycle (IPC) of 3DRA with different number of FIFO entries for the PEs. To show how the dynamic data driven execution can improve the performance, 3DRA is compared with a statically programmed Coarse Grained Reconfigurable Arrays (CGRA) which demionstrated high performance and efficiency using its multi-hop data transfer. In a statically programmed reconfigurable architecture, Initiation Interval (II) which means the time gap between two consecutive iterations is fixed, meaning that the iterations are repeated in every II cycles. For the comparison its IPC is calculated as #Nodes/II. In the described experiments, the number of 3DRA is set as 171 to be capable of mapping all the benchmarks in Table 1. 3DRA demonstrated that the higher IPC than the baseline and it improves as the FIFO size grows while the performance benefit of FIFO sizes diminish after 16 in all applications. The experiments demonstrate that advantages of incorporating of FIFO in the disclosed circuits is significant. It can be slower than the baseline (e.g., kernel symm) when there exists memory port contention between memory operations. In the current design of 3DRA, by selecting a memory access in a round robin manner, it can be different from the optimal memory access order.

TABLE 2
Impact of the number of PEs over frequency,
power, and area. The number of memory ports
is fixed as 4 and the input FIFO size is 16.

| # of PEs | Frequency (MHz) | Power (mW) | Area (mm²) |
|---|---|---|---|
| 64 | 690 | 18.25 | 0.572 |
| 128 | 546 | 23.78 | 1.135 |
| 256 | 351 | 24.97 | 2.229 |

Number of PEs: As a PE handles a single instruction, the maximum ILP is limited by the number of PEs. Through conventional characterization studies, it is understood that about 90% of conventional executions for computation comprise of 51 to 264 instructions. Besides ILP, the number of PEs can significantly affect the frequency, power, and area of the computing circuit mainly due to its all-to-all communication method. In Table 2, the impact of the number of PEs is shown where the number of memory controllers (or memory ports) are fixed as 4 and the FIFO size is fixed as 16. It is observed that the frequency drops quickly when the number of PEs is increased from 128 to 256. Before placement and routing, 3DRA can reach about 924 MHz frequency. The frequency drops further when the number of PEs grows as it becomes more challenging to optimize the placement and routing. We can expect to reach higher frequency with improved placement and routing techniques when it has many PEs.

Power efficiency: 3DRA could demonstrate a large degree of parallelism with low power consumption compared to other reconfigurable architectures. FIG. 8 shows the power efficiency of 3DRA in various configurations and power efficient CGRA implementations. In HyCUBE's case, its power efficiency is based on a recent study with heterogeneous PEs. In experiments, 3DRA demonstrated the highest level of power efficiency when it had 64 PEs and runs at 300 MHz. SNAFU is specialized in ultra-low-power computing while HyCUBE aims for high performance consuming relatively higher power. 3DRA demonstrated energy efficient high performance reaching over 8,000 MIPS at 7.43 mW.

TABLE 3
Power breakdown of the 3DRA with 128 PEs,
4 memory ports, and 16 input FIFO entries.

| | Power(mW) | | | |
|---|---|---|---|---|
| | # | Static | Dynamic | Total |
| Compute Unit | 128 | 0.12 | 3.92 | 4.04 (20.61%) |
| FIFO | 3 × 128 | 0.12 | 10.42 | 10.54 (53.78%) |
| SRAM | 1 | 2.62 | — | 2.62 (13.37%) |
| Total | — | 0.27 | 16.70 | 19.6 |

Power breakdown: In Table 3, the power breakdown is demonstrated. As the power consuming switching network used in the background art is not included in the described embodiments, most of the power is spent to buffer incoming data at input FIFOs and computation. In FIG. 7, it shows that there exist application kernels that do not benefit much from the large FIFOs. In such cases, when the power budget is tight or higher power efficiency is required, embodiments may be configured with reduced FIFO size. Alternative the input FIFOs may be replaced with registers to save power.

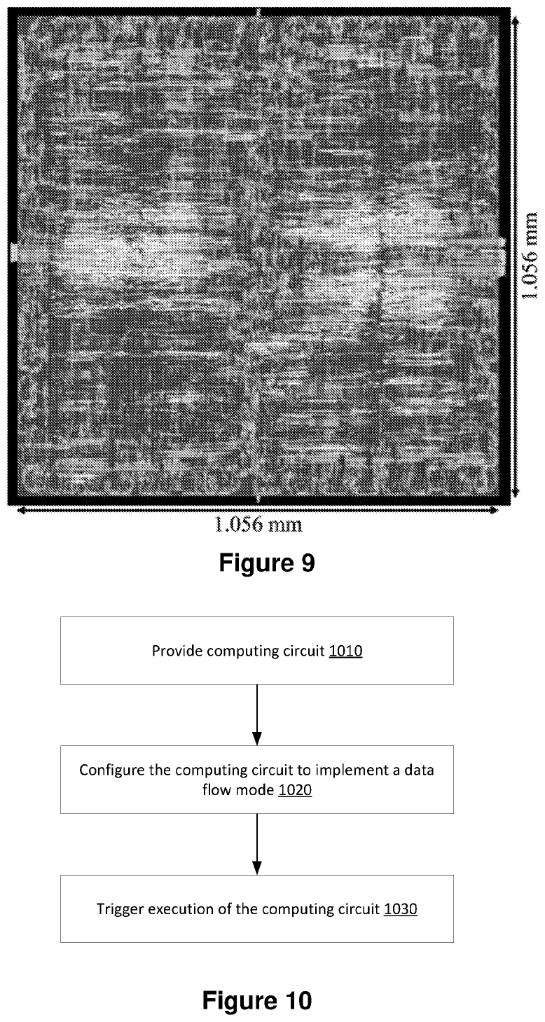

The embodiments demonstrated considerably high frequency even if hundreds of PEs were incorporated in the computing circuit. The separation of critical paths such as data broadcasting lines, communication lines to memory components and lines to ALUs allow provision of the higher frequency computations in the disclosed computing circuits. FIG. 9 shows an exemplary floorplan of the 128-PE version of 3DRA. Its width and length both have 1,056 μm, which leads to the area of Computing circuit comprising a circuit for performing computations, including computations implementing a data flow model or a control data flow graph (CDFG).

FIG. 10 illustrates a method of execution of a data flow model using a computing circuit according to the embodiments. Step 1010 comprises providing a computing circuit. The computing circuit may comprise a suitable number of PEs for the data flow model intended to be executed. At step 1020, the PEs of the computing circuit are configured to execute the data flow model. This may comprise, breaking down the data flow model into discrete computations, wherein each discrete computation is capable of being performed by a single PE. Each discrete computation may include its operation, operands and any memory access operations. The configuration step also includes definition of the communication lines between the PEs performing each discrete computation such that results of the discrete computations flow according to the data flow model to generate a final output. After the computing circuit is configured, at step 1030, execution is trigged to obtain a final result of the computation.

Data flow model comprises a model with a definition of computations, including interdependent computations to compute a result based on input. A CDFG is an example of a data flow model. Data flow models may be broken down into discrete computations arranged in a graph or a graph like structure. Each node of the graph relates to a discrete computation forming part of the data flow model. Each branch or connection of the graph relates to a path for the flow of inputs or outputs. FIG. 6a illustrates an example of a data flow model.

A ready to receive output signal is a signal from a processing element to the rest of the PEs indicating that it is ready to receive output of the rest of the Pes. The ready receive output signal may be generated based on whether the FIFO queue of the PE is full or not full.

The phrase “data communication lines connecting an output port of each of the PEs with an input port of each other one of the PEs” refers to an output of each PE being connected to an input of every other PE, but not to its own input port.

Operand memory is the memory provided for each PE to store operands for performing computations. i1, i2 . . . p illustrated in this disclosure are examples of operand memory.

Processing cycle is a period of time over which a discrete action such as a computation or transmission of output is performed by the various elements of the computing circuit. The processing cycle may also be referred to as a clock cycle. The processing cycle also serves as a underlying timing mechanism to coordinate the actions of the various elements of the computing circuit.

External memory relates to memory accessible to the PEs apart from the operand memory. External memory controller performs the coordination of the retrieval from and/or writing to the external memory by the PEs.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavor to which this specification relates.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Although this disclosure describes or illustrates particular embodiments as providing particular advantages, particular embodiments may provide none, some, or all of these advantages.

1. A computing circuit comprising:
a plurality of reconfigurable processing elements (PEs);
data communication lines connecting an output port of each of the PEs with an input port of each other one of the PEs;
wherein the computing circuit is configured to execute a data flow model by configuring at least a subset of the plurality of PEs to perform a respective discrete computation implementing the data flow model; and
wherein a first PE of the subset of PEs is configured to perform its respective discrete computation on receipt of a ready to receive output signal from one or more destination PEs.

2. The computing circuit of claim 1, wherein the one or more destination PEs are configured to perform a computation using the output of the first PE according to the data flow model.

3. The computing circuit of claim 1 further comprising an operand memory provided for each PE to store a plurality of input operands;
wherein the first PE is configured to perform the discrete computation after determining the receipt of all input operands of its respective discrete computation in its operand memory.

4. The computing circuit of claim 3, wherein the operand memory implements a first in first out (FIFO) queue to store the input operands.

5. The computing circuit of claim 4, wherein while the FIFO queue of a first destination PE is not full, the first destination PE transmits a ready to receive output signal to the rest of the plurality of PEs.

6. The computing circuit of claim 3, wherein the receipt of all input operands is determined in every processing cycle by the first PE.

7. The computing circuit of claim 3, wherein each of the plurality of input operands are stored in a register; and
the register is populated by a multiplexer connected to data communication lines transmitting data from output port of each of the PEs.

8. The computing circuit of claim 7, wherein each multiplexer is configured to populate the operand memory using output of one of the PEs based on a reconfigurable source index register comprising an index information of the one of the PEs designated as input.

9. The computing circuit of claim 1, wherein the output of each PE is transmitted to each of the rest of the PEs over the data communication lines in a single processing cycle.

10. The computing circuit of claim 1, wherein each PE comprises an arithmetic logic unit (ALU) to perform its respective discrete computation and an Opcode register storing a code designating the computation to be performed by the ALU.

11. The computing circuit of claim 1, wherein each PE is configured to receive in its memory input operands for a subsequent computation while performing its respective discrete computation.

12. The computing circuit of claim 1, further comprising one or more external memory controller configured to:
receive request from a requesting PE among the plurality of PEs for loading data stored in an external memory;
query the external memory based on the received requests:
obtain a response from the external memory; and
provide the obtained response to the requesting PE.

13. The computing circuit of claim 1, wherein the data flow model is a control dataflow graph (CDFG).

14. A method of executing a data flow model, the method comprising:
providing the computing circuit of claim 1;
configuring at least a subset of the plurality of PEs of the computing circuit to perform a plurality of discrete computation implementing the data flow model; and
triggering execution by the computing circuit.

15. A reconfigurable computing architecture comprising a main memory, memory controllers, processing elements (PEs) and multiplexers, wherein the PEs are deployed to increase the degree of parallelism and to satisfy the conditions of dynamic data-driven execution;
a PE has the same number of input ports with the number of PEs, so that it can get any input data that the multiplexers pick as programmed without an input port contention;
the PEs are connected in such a way that data can be broadcast directly to all existing PEs in a single cycle to reduce communication latency;
the memory controllers are used to send load and store requests from the PEs and forward loaded data from the memory to the PEs; and
all of the PEs have the same design and are connected to the memory controllers and other PEs via data broadcasting lines.

16. A method of executing a data flow model, the method comprising:
providing the computing circuit of claim 3;
configuring at least a subset of the plurality of PEs of the computing circuit to perform a plurality of discrete computation implementing the data flow model; and
triggering execution by the computing circuit.

17. A method of executing a data flow model, the method comprising:
providing the computing circuit of claim 6;
configuring at least a subset of the plurality of PEs of the computing circuit to perform a plurality of discrete computation implementing the data flow model; and
triggering execution by the computing circuit.

18. A method of executing a data flow model, the method comprising:
providing the computing circuit of claim 8;
configuring at least a subset of the plurality of PEs of the computing circuit to perform a plurality of discrete computation implementing the data flow model; and
triggering execution by the computing circuit.

19. A method of executing a data flow model, the method comprising:
providing the computing circuit of claim 10;
configuring at least a subset of the plurality of PEs of the computing circuit to perform a plurality of discrete computation implementing the data flow model; and
triggering execution by the computing circuit.

20. A method of executing a data flow model, the method comprising:
providing the computing circuit of claim 12;
configuring at least a subset of the plurality of PEs of the computing circuit to perform a plurality of discrete computation implementing the data flow model; and
triggering execution by the computing circuit.
